(19) United States
(12) Patent Application Publication
(10) Pub. No.: US 2025/0258606 A1
(43) Pub. Date: Aug. 14, 2025

(54) PHOTONIC MEMORY FABRIC FOR SYSTEM MEMORY INTERCONNECTION

(71) Applicant: Celestial AI Inc., Santa Clara, CA (US)

(72) Inventors: David LAZOVSKY, Los Gatos, CA (US); Philip WINTERBOTTOM, San Jose, CA (US); Martinus BOS, San Jose, CA (US)

(21) Appl. No.: 19/172,441

(22) Filed: Apr. 7, 2025

Related U.S. Application Data
(63) Continuation of application No. 17/903,455, filed on Sep. 6, 2022, now Pat. No. 12,271,595.
(60) Provisional application No. 63/321,453, filed on Mar. 18, 2022.

(51) Int. Cl. G06F 3/06; G02B 6/12; G02B 6/122; G02B 6/42; H04Q 11/00

(52) U.S. Cl. CPC G06F 3/0611; G02B 6/12019; G02B 6/1225; G02B 6/4246; G06F 3/0655; G06F 3/0679; H04Q 11/0062

(57) ABSTRACT

One embodiment is a method that includes generating a request for a data item in a memory, obtaining the data item from the memory with a photonic interface, sending the data item to a fabric using a transmit unit of the photonic interface, and routing the data item through a portion of the fabric coupled to the memory, the portion of the fabric including one or more additional transmit and receive units between the photonic interface and a destination receive unit.

### CROSS-REFERENCE TO RELATED APPLICATIONS

The present application claims priority to and incorporates by reference U.S. patent application Ser. No. 17/903,455, filed on Sep. 6, 2022 which claims priority to U.S. Provisional Patent Application Ser. No. 63/321,453, entitled PHOTONIC MEMORY FABRIC FOR MEMORY INTERCONNECTION, filed on Mar. 18, 2022. The present application incorporates by reference, in its entirety, U.S. patent application Ser. No. 17/807,694, entitled MULTI-CHIP ELECTRO-PHOTONIC NETWORK, filed on Jun. 17, 2022.

### BACKGROUND

Current electronic processing systems are increasingly constrained by memory latency and bandwidth. As silicon processing node sizes have decreased, the speed and energy consumption of computation have improved while the interconnection to memory has not kept pace. Where improvements in memory bandwidth and latency have been achieved, it has been at the cost of imposing significant constraints on signal integrity and complexity of packaging. State-of-the-art high bandwidth memory (HBM) dynamic random-access memory (DRAM) requires the memory to be mounted on a silicon interposer to be placed within a few millimeters of the client device that uses the memory, with pins that run over electrical wires at over 3 GHz, imposing signal-integrity as well as thermal constraints that are both complex and expensive to meet. Moreover, the need to place the memory elements close to the chips that use them highly constrains the number and arrangement of HBM stacks around the client device and places significant restrictions on the total amount of memory that can be integrated into such a conventional system.

### SUMMARY

One embodiment is an apparatus coupled to a memory. The apparatus comprises an interface associated with the memory, the interface having a first transmit unit for sending data from the memory and a first receive unit for receiving data sent to the memory, a fabric connected to the first transmit and receive units, the fabric including a plurality of routers, each of the routers having additional transmit and receive units, the routers arranged in a grid formed by connecting the additional transmit units with the additional receive units via optical links, and a first mesh coupled to a first portion of the memory, the first mesh including a first portion of the routers that create a first connection between the first transmit and receive units and a local electrical router associated with a first one of the routers.

Another embodiment is a system. The system comprises an interface system associated with the memory subsystem, the interface system having a first transmit unit for sending data from the memory subsystem and a first receive unit for receiving data sent to the memory subsystem, a fabric system connected to the first transmit and receive units, the fabric including a plurality of routers, each of the routers having additional transmit and receive units, the routers arranged in a grid formed by connecting the additional transmit units with the additional receive units via optical links, and a first mesh system coupled to a first portion of the memory subsystem, the first mesh system including a first portion of the routers that create a first connection between the first transmit and receive units and a local electrical router associated with a first one of the routers.

Yet another embodiment is a method. The method comprises generating a request for a data item in a memory, obtaining the data item from the memory with a photonic interface, sending the data item to a fabric using a transmit unit of the photonic interface, and routing the data item through a portion of the fabric coupled to the memory, the portion of the fabric including one or more additional transmit and receive units between the photonic interface and a destination receive unit.

### BRIEF DESCRIPTION OF THE DRAWINGS

FIG. 1 is a diagram of a photonic memory fabric for system memory interconnection according to one embodiment.

FIG. 2 is a diagram of one embodiment of a photonic channel for use in a memory fabric for system memory interconnection.

FIG. 3 is a diagram of another embodiment of a photonic channel for use in a memory fabric for system memory interconnection.

FIG. 4 is a diagram of an embodiment of a transmitter and a receiver that can be used in a memory fabric for system memory interconnection.

FIG. 5 is a diagram of an embodiment of a message router that can be used in a memory fabric for system memory interconnection.

FIG. 6 is a diagram showing an example of the ports that can be used in a router in a memory fabric for system memory interconnection.

FIG. 7 is a diagram of a conventional HBM subsystem.

FIG. 8 is a diagram of an HBM subsystem according to one embodiment.

FIG. 9 is a diagram of a photonic memory fabric connected to a variety of memory types according to one embodiment.

FIG. 10 is a diagram of a photonic memory fabric for system memory interconnection according to one embodiment.

### DETAILED DESCRIPTION

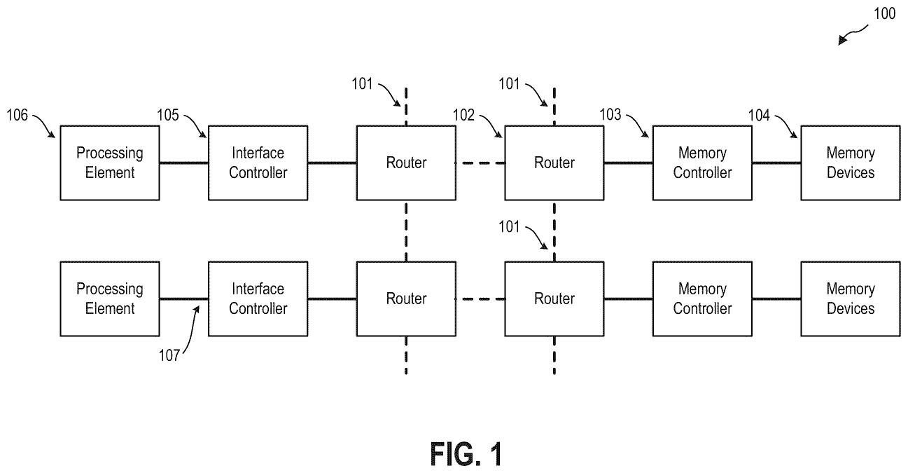

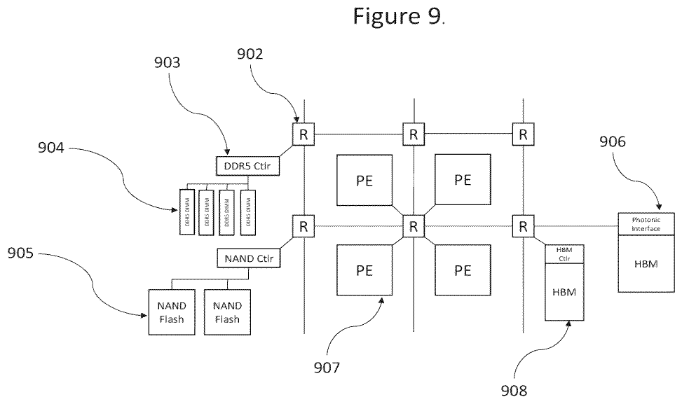

The present application discloses an innovative memory fabric. At least one embodiment of an apparatus, system, or method described herein addresses the location, signal-integrity, and bandwidth constraints of current memory system architectures. As shown in FIG. 1, a memory fabric (100) in accordance with some embodiments includes four main components: a set of one or more photonic channels (101), optionally one or more message routers (102) that enable composition of links into a fabric, one or more memory controllers (103) to connect standard memory devices (104), and one or more interface controllers (105) to connect to processing elements (106). Connections between the routers (102) are made using photonic links (e.g., optical links), whereas the other connections in FIG. 1 may use alternatively electrical buses (107) or photonic links. In certain embodiments, e.g., as described below with reference to FIG. 9, the interface controllers (105) of the processing elements (106) connect electrically to the routers (102), whereas one or more memory controllers (103) are augmented by photonic interface controllers that connect optically to the routers (102) and/or directly to processing elements (106). Many topologies are possible that use one or more photonic links and zero or more routers; examples are described further below.

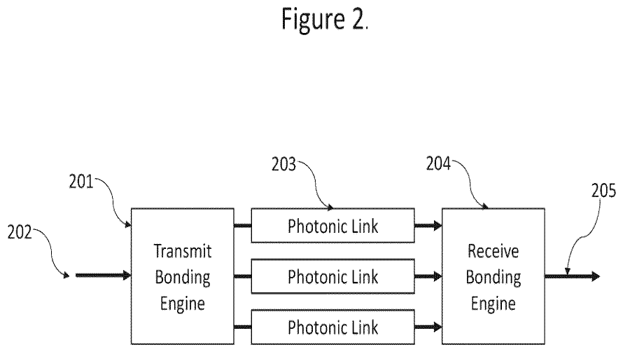

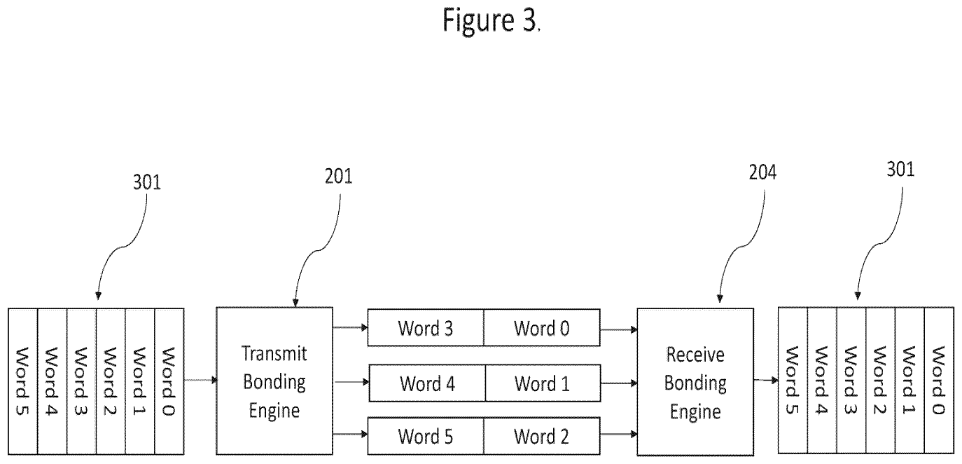

A photonic channel contains two unidirectional sets of (one or more) links capable of making a bi-directional channel for transferring a message in the form of a variably sized packet. As shown in FIGS. 2 and 3, multiple unidirectional links in one direction may be bonded together to form a single logical channel that can transfer messages. In this embodiment, a message (202) consisting of a sequence of, e.g., 256-bit words (301) is presented to the transmit bonding engine (201). The transmit bonding engine (201) may split the words (301) evenly across the active photonic links (203). In the depicted example, data (e.g., a data item) arrives at the receive bonding engine (204) on three links. Sequence information added to the words (301) by the transmit bonding engine (201) permits the original message (202) to be assembled in order and sent on the output interface (205) of the receive bonding engine (204). Bonding allows high-bandwidth, low-latency channels to be constructed from several lower-bandwidth links and provides the ability to configure out non-working links.

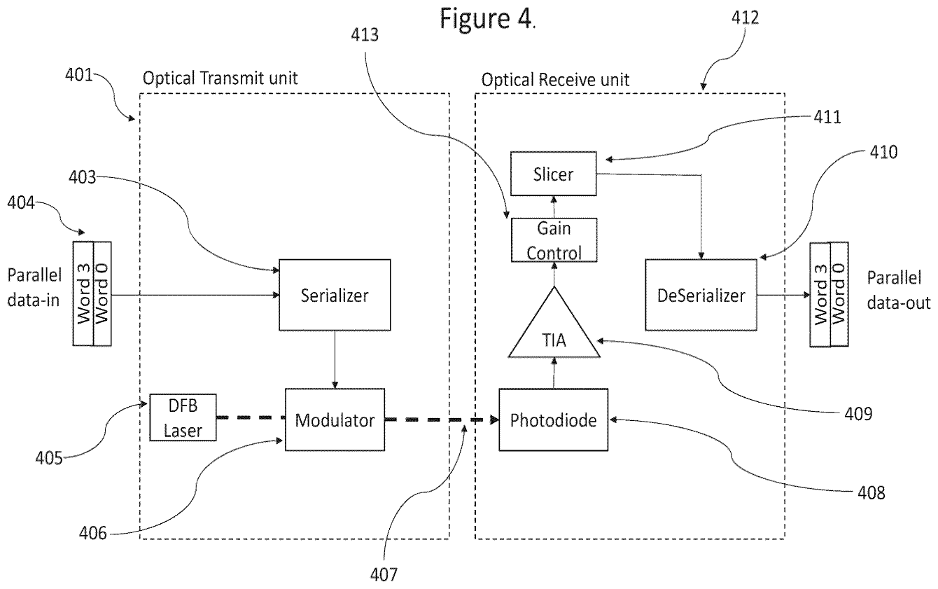

As shown in FIG. 4, each link (e.g., 203) in a photonic channel includes an optical transmit unit (401), an optical receive unit (412), and an optical transmission medium (407) (e.g., an optical waveguide or fiber) connecting the transmit unit (401) to the receive unit (412). The transmit unit (401) includes an optical modulator (406) that imparts a message onto an optical signal by modulating carrier light output by a light source (405), and an electrical serializer (403) that converts an electronic message received in the form of parallel data words (404) into a signal suitable for driving the optical modulator (406). The optical modulator (406) may include an electro-absorption modulator (EAM), a micro-ring resonator, a ring modulator, a Mach-Zender interferometer (MZI), and a quantum confined stark effect (QCSE) electro-absorptive modulator. The optical modulator (406) may be coupled to a driver. In some embodiments, the driver is a photonic-integrated circuit (PIC) or a electronic-integrated circuit (EIC) (e.g., as described in connection with U.S. patent application Ser. No. 17/807,694, entitled MULTI-CHIP ELECTRO-PHOTONIC NETWORK, filed on Jun. 17, 2022, which is hereby incorporated by reference in its entirety). The transmit unit (401) sends data (e.g., from one or more memory devices (104)) to the receive unit (412). The receive unit (412) includes a photodiode (408) to convert the optical signal received via the transmission medium (407) back to an electrical signal, and associated electronics including a transimpedance amplifier (409) and gain control to normalize the signal level (413), a slicer (411) to extract the bit-stream, and a de-serializer (410) to convert the received message back into parallel data. The optical modulator (406) and the electrical serializer (403) are coupled together by an electrical connection such as a copper pillar or C4 bump. Likewise, the photodiode (408) and the transimpedance amplifier (409) are also coupled together via an electrical connection like a copper pillar or C4 bump.

The optical transmission medium (407) may include a waveguide on a photonic-integrated circuit (PIC), an optical fiber or other optical transmission medium (such as free space optics or glass-etched waveguide), or some combination of the foregoing. Examples of optical modulators (406) include, but are not limited to, electro-absorption modulators (EAMs) and micro-ring resonators. The light source (405), which is conceptually part of the transmit unit (401), may be shared between transmit units of multiple photonic links. The light source(s) (405) feeding the modulators (406) may be located locally on the PIC or connect to the PIC via optical fiber. When integrated onto the PIC, distributed fiber Bragg (DFB) lasers or quantum dot lasers can be attached during processing or integrated in the native technology where possible. When remote, any packaged continuous wave (CW) laser suitable in power and spectrum for the modulation technology may be used. In one embodiment, the light source is a set of DFB lasers attached to a silicon interposer and connected to the PIC via optical fibers. In one embodiment, the link is modulated at 56 Gb/s in a non-return-to-zero (NRZ) code, but more spectrally efficient modulation schemes, such as PAM-4 or PAM-8 or higher-order pulse amplitude modulation, may be used to allow higher-bandwidth and lower-latency links.

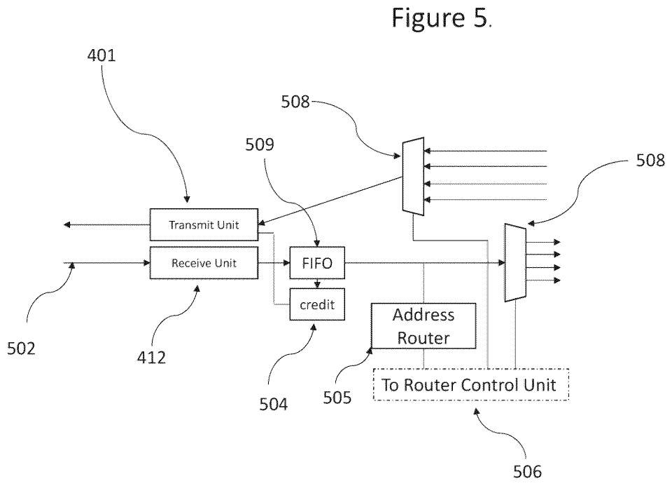

A photonic channel can be used to directly connect a memory subsystem in a point-to-point fashion, providing dedicated bandwidth between the memory subsystem and a processing element. However, in some embodiments, more complex topologies are created by introducing a routing element that dynamically routes messages between the photonic channels. When a router is used, a portion of the message (e.g., a data item, a first data item, a second data item) having routing information can include the address of the destination photonic-fabric channel, an identifier associated with a compute or a memory mesh, or the like. As shown in FIG. 5, a message arriving at the router is processed by an address router (505) unit that extracts the destination address while the arriving message is stored in a FIFO (first in-first out) buffer (509). A routing algorithm (e.g., a routing module) uses the address bits to select an egress port selected by an output multiplexor (508) based on the fabric topology and routing policy. Coordination of the port units depicted in FIG. 5 are controlled by a router control unit (506) that connects to the data input/output multiplexors (508) and the address router (505) in each port. The router control unit (506) resolves port contention when traffic arrives for the same egress port. In some embodiments, the routing algorithm moves data (e.g., a data item, a first data item, a second data item) between two areas of memory that are each separately linked to a mesh (e.g., a first mesh and a second mesh).

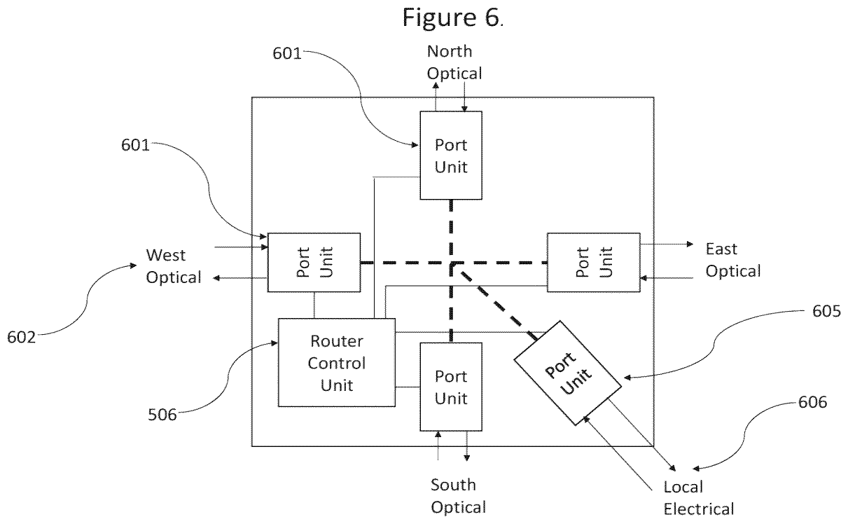

Many topologies and routing algorithms are possible for the fabric or a portion of the fabric, such as hyper-cube or mesh. In various embodiments, the topology is a mesh or wrapped mesh. In such a system, each router has four optical ports and one electronic port. As shown in FIG. 6, the four optical ports (601) are connected to the north, south, east, or west routers in the fabric. The port unit multiplexors (508) are connected electrically within the router to provide full connectivity between the port units. The router control unit (506) takes request from the various port units and grants access to an egress port in such a fashion that contentions are resolved. Port units may have optical interfaces (602) or electronic interfaces (606) (e.g., a local electrical router) based on their destination. The local port (605) to resources connected to the router will typically be electrical while the connections between routers are usually photonic. In such a system, a convenient addressing scheme encodes the number of steps left in the north/south or east/west direction. A positive number encodes a move north or east, a negative number south or west. As a message traverses a set of routers, if the message moves north, the north/south portion of the address is decremented; likewise, if the message moves south, the north/south portion of the address is incremented. Equivalently, if the message moves east, the east/west portion of the address is decremented, and if the message moves west, it is incremented. The message address is initialized with the number of steps in each direction required to reach the destination. When both the north/south and east/west fields are zero, the message has arrived at the destination and is delivered to the electrical port.

At the electronic port of each router or at the end of a photonic link in point-to-point architectures, a controller converts messages into a bus protocol that can ultimately be used to access the connected memory. Two examples of such protocols are Peripheral Component Interconnect Express (PCIe) and Advanced Extensible Interface (AX). In one embodiment, AXI transactions are forwarded over the memory fabric. The messages router uses the top 10 bits of the AX address to specify the fabric destination and a further 32 bits to specify memory access information, such as an offset (e.g., memory access information) in the target memory controller. To prevent the ingress FIFOs of the router from overflowing, a flow control scheme should be implemented to control the number of messages in flight in the fabric. This is accomplished by a credit flow control mechanism. A port is initialized with a number of tokens representing memory transactions that are smaller in number than the FIFO at the other end of the link. Every time a new transaction is sent on a link, a credit register (504) on the egress port is examined. Each memory transaction is a certain number of credits in size. If there are more than memory transaction size credits in the egress port credit register, then transmission can proceed, and the number of tokens is reduced by memory transaction size credits. If there are insufficient credits, the transmission is stalled. When a receiver process removes a message from the ingress FIFO, a credit message with memory transaction size credits is sent back on the link. Upon receiving the credit, the egress credit register is incremented, and if sufficient credits are now available to transmit any stalled messages, the transmission process can be restarted. Dynamic routing decisions are made when alternate valid routes are available. In such a case, the path with most credits is selected, which provides load balancing within the fabric.

The photonic links and photonic fabric described above can be employed to provide photonic connection to generally any memory subsystem augmented with a suitable photonic interface controller. As herein understood, a memory subsystem includes a set of one or more memory devices and a memory controller coupled to the set of memory devices to provide access to data stored thereon. The photonic interface controller connects the memory controller to the photonic interface (e.g., interface system) associated with a photonic channel, such as with the optical modulator and photodetector of a bidirectional channel. The memory controller and photonic interface controller may be implemented in separated die that interface with each other, or alternatively in a single die. In some embodiments, the memory subsystem is a memory stack device that includes a stack of DRAM die.

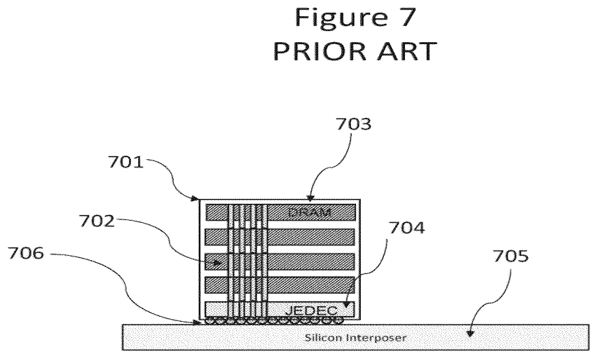

Photonic memory connections as described are especially useful to implement complex, scalable HBM (701) systems. In a conventional HBM subsystem, as shown in FIG. 7, a stack of DRAM (703) die is connected using through-silicon via (TSV) technology (702). At the base of the stack, a DRAM controller presents a Joint Electron Device Engineering Council (JEDEC) (704) compliant interface out of the bottom the stack that connects to the system via a silicon interposer (705) using bump attach (706) and a DRAM control interface up into the DRAM stack above to access the memory itself and perform bookkeeping tasks such as memory refresh.

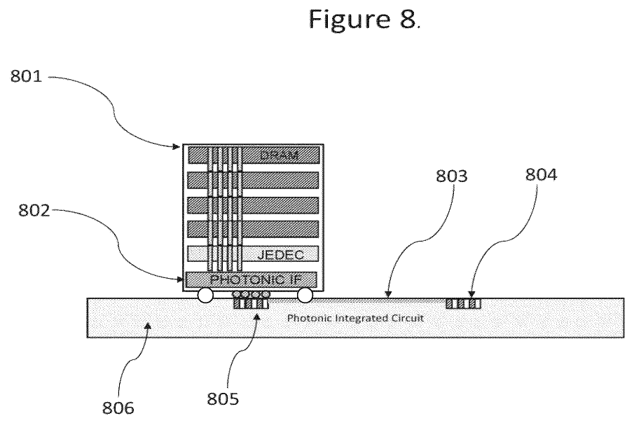

In an example implementation of photonically connected memory in accordance with an embodiment, illustrated in FIG. 8, an additional controller layer (802) is added to the base of the HBM stack (801). This additional controller layer (802) serves as a photonic interface controller that connects the (standard) DRAM controller to the optical modulator and photodetector of a bidirectional channel. Thus, addition of this controller layer (802) converts the standard HBM JEDEC interface into a photonic-fabric interface that in turn connects to the modulators and photodiodes (805) in the photonic-integrated circuit (806). This arrangement enables the use of standard HBM modules connected over long distances, using waveguides (803), optical fibers, or some other optical transmission media that finally terminate in another fabric interface elsewhere in the system (804). In an alternative embodiment, the DRAM controller and the photonic interface controller are integrated into a single layer (or single functional unit) at the base of the HBM stack for further optimization.

The memory fabric architecture is agnostic to the type of connected memory. As shown in FIG. 9, different memory controllers allow connecting different types of memory to the photonic memory fabric. In the depicted embodiment, the core of the system is an arrangement of processing elements (907) that are electrically connected to photonic routers (902), which are in turn connected in a sub-fabric or mesh. Memory controllers can then be connected to either the electrical ports of the routers (as shown for memory controller (903)) or, when augmented by or integrated with a photonic interface controller (906), via a photonic channel to a photonic port of the router. Non-limiting examples of memory types for which it is desirable to provide connectivity are NAND Flash memory (905) (including but not limited to solid-state drive (SSD) memory), NOR Flash memory (including conventional CMOS memory and thin film transistor-based memory), phase change memory (PCM), storage class memory (SCM) such as Optane, magneto-resistive memory (MRAM), resistive RAM (ReRAM or RRAM), and traditional DRAM (including HBM (908) and DDR-based DRAM (904). An HBM equipped with a photonic interface controller (906) layer that includes a routing element provides a scalable photonically connected memory that can be stacked like DIMM memory. A selection of memory controllers with different interfaces permits the construction of both heterogenous and homogenous memory systems (e.g., a combination of multiple types of the memories described above).

An important aspect of the memory fabric is to enable the construction of complex topologies of memories that best serve the application requirements. While this discussion of topologies focuses on HBM, it is equally applicable to other types of memory. In the simplest arrangement, a set of point-to-point channels connect an HBM stack to one or more fabric interfaces located in the same or several chips. The benefit of this arrangement is two-fold. First, the system designer is relieved of the distance constraints of the HBM JEDEC interface, and the HBM memory can be placed arbitrarily far from the client chip if it is within the optical budget of the photonic links (typically several meters). This permits higher-density memory systems than can currently be constructed using electrical interfaces. Furthermore, there can be significant energy savings when the photonic fabric interface is located at the center of a large die, where photonic transport of the data is more efficient than an equivalent high-bandwidth electrical interconnect in the client chip itself. The second benefit derives from being able to control the power density of the system by spacing the memory and client chips (e.g., implementing processing elements) to optimize cooling efficiency, as the distances are no longer dictated by the electrical interfaces. More complex topologies can be composed by integrating routers in both memory and client-chip components. The use of photonic memory fabrics permits arbitrary grouping of memory and client chips that best serve the bandwidth and connectivity needs of applications. Groups of memory can surround a client chip on a single interposer, and several chips and memory can be integrated onto a single interposer. Special-purpose memory and compute subsystems on separate interposers can be networked together using any of the optical transport mediums outlined above, and using a mixture of fabric topologies that may vary from a single or set of point-to-point links aggregated on ribbon fibers to mesh and hyper-cube topologies providing significantly richer and higher bandwidth topologies that utilize various collections of waveguides and optical fibers to connect the components.

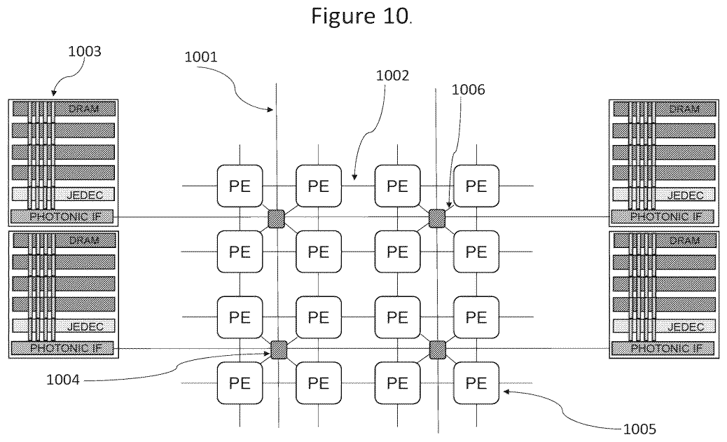

The disclosed memory fabric may be used to augment the processing system described in the U.S. patent application entitled “MULTI-CHIP ELECTRO-PHOTONIC NETWORK”, which has been incorporated by reference herein. Memory and compute traffic over a photonic fabric have different characteristics: compute traffic usually involves short hops between adject processing elements, while memory traffic often travels long distances from memory arrays located away from the processor but requires very high bandwidth to support HBM memory. As shown in FIG. 10, in one beneficial implementation, a balance can be achieved by overlaying two mesh networks—a memory mesh (1001) and a compute mesh (1002). The compute mesh (1002) is a densely connected nearest-neighbor mesh connecting all of the processing elements (1005) in the system. The memory mesh (1001) is a lower-density mesh with wider channels that feeds groups of compute elements from router nodes (1004) placed equidistant from a cluster of processing elements (1005) and connects (1006) directly to memory subsystems (1003). The architectural split of memory and compute networks allows each to be optimized for the magnitude of data, traffic patterns, and bandwidth of each fabric application.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A system-in-package, comprising:
a computing resource; and
an interface associated with the computing resource, the interface comprising:
a first transmit unit for sending data from the computing resource via a first optical link, wherein the first transmit unit comprises a driver connected to a modulator, the driver and the modulator being implemented in a first semiconductor layer, and a serializer in a second semiconductor layer, the driver being connected to the serializer, wherein the serializer provides an output to the driver; and
a first receive unit for receiving data sent to the computing resource via a second optical link, wherein the first receive unit comprises a photodetector in the first semiconductor layer, and a deserializer in the second semiconductor layer.

2. The system-in-package of claim 1, wherein the first optical link comprises a first waveguide from the modulator to a second receive unit associated with a second computing resource.

3. The system-in-package of claim 2 wherein the second optical link comprises a second waveguide from a second transmit unit associated with the second computing resource to the photodetector.

4. The system-in-package of claim 3, further comprising a third transmit unit for sending data from the computing resource via a third optical link wherein the first transmit unit comprises a second driver connected to a second modulator in the first semiconductor layer, and a second serializer in the second semiconductor layer,
wherein the third optical link comprises an optical pathway that uses an optical interface that guides light from a waveguide into a fiber.

5. The system-in-package of claim 1, wherein a spacing between the driver and the modulator is less than two-hundred microns.

6. The system-in-package of claim 1, wherein the computing resource is one or more of a memory element or a processing element.

7. The system-in-package of claim 1, wherein the first receive unit comprises an amplifier in the second semiconductor layer connected to the deserializer, the deserializer receiving an input from the amplifier.

8. The system-in-package of claim 1, wherein the first semiconductor layer is a photonic integrated circuit (PIC), and wherein the second semiconductor layer is an electronic integrated circuit (EIC).

9. The system-in-package of claim 1, wherein the serializer converts an electronic message received in a form of parallel data into a signal suitable for driving the modulator, and wherein the deserializer converts a received message back into parallel data.

10. The system-in-package of claim 1, wherein the modulator is selected from the group consisting of an electro-absorption modulator (EAM), a micro-ring resonator, a ring modulator, a Mach-Zender interferometer (MZI), and a quantum confined stark effect (QCSE) electro-absorptive modulator.

11. The system-in-package of claim 1, wherein the computing resource is one or more of a NAND Flash memory, a solid-state drive (SSD) memory, a NOR Flash memory, a CMOS memory, a thin film transistor-based memory, a phase change memory (PCM), a storage class memory (SCM), a magneto-resistive memory (MRAM), a resistive RAM, a DRAM, an HBM, a DDR-based DRAM, or a DIMM memory.

12. The system-in-package of claim 1, wherein the computing resource includes a combination of at least one memory element that provides access to memory traffic and a processing element that provides access to compute traffic.

13. The system-in-package of claim 1, wherein the interface further comprises a multiplexer in the first semiconductor layer connected to a first side of the modulator for combining one or more inputs received from the modulator with one or more additional inputs received from one or more additional modulators in the first semiconductor layer.

14. The system-in-package of claim 13, wherein the interface further comprises a demultiplexer in the first semiconductor layer connected to a second side of the photodetector for separating wavelengths of one or more signals provided to the photodetector and one or more additional photodetectors.

15. The system-in-package of claim 1, further comprising an edge coupling in the first semiconductor layer connecting a fiber to a waveguide formed in the first semiconductor layer such that an optical signal from a light source can be delivered to the modulator via the waveguide.

16. The system-in-package of claim 1, wherein the interface further comprises at least one additional transmit unit for sending data from the computing resource via a first one or more additional optical links of a bidirectional channel and at least one additional receive unit for receiving data sent to the computing resource via a second one or more additional optical links of the bidirectional channel.

17. The system-in-package of claim 16, wherein the interface further comprises a transmit bonding engine for combining the data sent from the computing resource across the first optical link and the first one or more additional optical links and a receive bonding engine for separating received data sent to the computing resource across the second optical link and the second one or more additional optical links.

18. The system-in-package of claim 1, wherein the first receive unit further comprises:
a gain control to normalize a signal level of a signal containing the data sent to the computing resource via the second optical link; and
a slicer to extract a bit-stream that is provided as an input to a de-serializer for converting the data sent to the computing resource into parallel data.

19. A system-in-package, comprising:
a first computing resource;
a second computing resource; and
a fabric coupled to the first computing resource and the second computing resource, the fabric comprising:
a first interface associated with the first computing resource, the first interface comprising:
a first transmit unit for sending data from the first computing resource via a first optical link of a bidirectional channel, the first transmit unit comprising a first driver connected to a first modulator, the first driver and the first modulator being implemented in a photonic integrated circuit (PIC), and a first serializer in a first electronic integrated circuit (EIC), the first driver being connected to the first serializer, wherein the first serializer provides a first output to the first driver; and
a first receive unit for receiving data sent to the first computing resource via a second optical link of the bidirectional channel, the first receive unit comprising a photodetector in the PIC, and a first deserializer in the first EIC; and
a second interface associated with the second computing resource, the second interface comprising:
a second transmit unit for sending data from the second computing resource via the second optical link of the bidirectional channel, the second transmit unit comprising a second driver connected to a second modulator, the second driver and the second modulator being implemented in the PIC, and a second serializer in a second EIC, the second driver being connected to the second serializer, wherein the second serializer provides a second output to the second driver; and
a second receive unit for receiving data sent to the second computing resource via the first optical link of the bidirectional channel, the second receive unit comprising a second photodetector in the PIC, and a second deserializer in the second EIC.

20. The system-in-package of claim 19, wherein each driver of the first driver and second driver is implemented within the PIC, wherein a spacing between each driver of the first driver and second driver and an associated modulator of the first modulator and the second modulator is less than two-hundred microns.

21. The system-in-package of claim 19, wherein each computing resource of the first computing resource and the second computing resource is one or more of a memory element or a processing element.

22. The system-in-package of claim 19, wherein each modulator of the first modulator and the second modulator is selected from the group consisting of an electro-absorption modulator (EAM), a micro-ring resonator, a ring modulator, a Mach-Zender interferometer (MZI), and a quantum confined stark effect (QCSE) electro-absorptive modulator.

23. The system-in-package of claim 19, wherein each computing resource of the first computing resource and the second computing resource is one or more of a NAND Flash memory, a solid-state drive (SSD) memory, a NOR Flash memory, a CMOS memory, a thin film transistor-based memory, a phase change memory (PCM), a storage class memory (SCM), a magneto-resistive memory (MRAM), a resistive RAM, a DRAM, an HBM, a DDR-based DRAM, or a DIMM memory.

24. A system-in-package comprising:
a first semiconductor layer including a driver having a first electrical connection to a modulator, the first semiconductor including a photodetector having a second electrical connection to an amplifier; and
a second semiconductor layer having a serializer providing output to the driver and a deserializer receiving input from the amplifier, the input and output passing through electrical connections between the first and second semiconductor layers,
wherein the first semiconductor layer includes a first waveguide coupled at a first side to an input fiber and at a second side to a first side of the modulator,
wherein the first semiconductor layer further comprises a second and a third waveguide, the second waveguide for carrying a first optical signal from the modulator to an additional photodetector, the third waveguide for carrying a second optical signal from an additional modulator to the photodetector.

25. The system-in-package of claim 24, wherein the first semiconductor layer is a photonic integrated circuit (PIC), and wherein the second semiconductor layer is an electronic integrated circuit (EIC).

26. The system-in-package of claim 24, wherein the modulator is selected from the group consisting of an electro-absorption modulator (EAM), a micro-ring resonator, a ring modulator, a Mach-Zender interferometer (MZI), and a quantum confined stark effect (QCSE) electro-absorptive modulator.

27. The system-in-package of claim 24, wherein the first semiconductor layer comprises a multiplexer connected to a second side of the modulator for combining one or more inputs received from the modulator with one or more additional inputs received from one or more additional modulators in the first semiconductor layer.

28. The system-in-package of claim 24, further comprising an edge coupling in the first semiconductor layer connecting the first fiber to the first waveguide such that an optical signal from a light source can be delivered to the modulator via the first waveguide.
